(19) United States
(12) Patent Application Publication
(10) Pub. No.: US 2024/0260332 A1
(43) Pub. Date: Aug. 1, 2024

(54) DISPLAY PANEL AND DISPLAY DEVICE

(71) Applicant: Shanghai Tianma Microelectronics Co., Ltd., Shanghai (CN)

(72) Inventors: Huifang ZHOU, Shanghai (CN); Zhongjie ZHANG, Shanghai (CN); Yi LIU, Shanghai (CN)

(21) Appl. No.: 18/632,553

(22) Filed: Apr. 11, 2024

(30) Foreign Application Priority Data
Jul. 24, 2023 (CN) 202310918016.X

(51) Int. Cl. H10K 59/122; H10K 59/124

(52) U.S. Cl. CPC H10K 59/122; H10K 59/124

(57) ABSTRACT

Provided are a display panel and a display device. The display panel includes a first display region, a base substrate, a planarization layer and a pixel defining layer. The first display region includes pixel regions and light-transmissive regions. The planarization layer is disposed on one side of the base substrate and at least in the pixel regions. The pixel defining layer is disposed on one side of the planarization layer facing away from the base substrate and in the pixel regions. The planarization layer includes flat portion and protrusion portion, in a direction facing away from the base substrate, protrusion portion protrudes from the flat portion, and a protrusion portion is at least partially located between the pixel defining layer and a light-transmissive region.

### CROSS-REFERENCE TO RELATED APPLICATION(S)

This application claims priority to Chinese Patent Application No. 202310918016.X filed Jul. 24, 2023, the disclosure of which is incorporated herein by reference in its entirety.

### TECHNICAL FIELD

The present disclosure relates to the field of display technologies and, in particular, to a display panel and a display device.

### BACKGROUND

At present, in the design of organic light-emitting diode display panels, the use of under-screen photosensitive elements (such as under-screen cameras) for display has become a trend. In this manner, the under-screen photosensitive element region can retain the display function, which greatly improves the integrity of the screen display.

Moreover, to ensure the transmittance of the under-screen photosensitive element region, a light-transmissive region needs to be disposed between pixel regions of the under-screen photosensitive element region. However, due to a certain degree of fluidity of the pixel defining layer of the pixel regions during preparation and a relatively small distance between a pixel region and a light-transmissive region, part of the pixel defining layer can easily flow to the light-transmissive region, shielding part of light of the light-transmissive region. As a result, the transmittance of the light-transmissive region is reduced, and then the function of the under-screen photosensitive element is affected.

### SUMMARY

The present disclosure provides a display panel and a display device to avoid the pixel defining layer flowing to the light-transmissive region, so that the transmittance of the light-transmissive region is improved, and thus the impact on the function of the under-screen photosensitive element is avoided.

In a first aspect, embodiments of the present disclosure provide a display panel. The display panel includes a first display region, a base substrate, a planarization layer and a pixel defining layer.

The first display region includes pixel regions and light-transmissive regions.

The planarization layer is disposed on one side of the base substrate and at least in the pixel regions.

The pixel defining layer is disposed on one side of the planarization layer facing away from the base substrate and in the pixel regions.

The planarization layer includes a flat portion and a protrusion portion, in a direction facing away from the base substrate, protrusion portion protrudes from the flat portion, and a protrusion portion is at least partially located between the pixel defining layer and a light-transmissive region.

In a second aspect, the embodiments of the present disclosure provide a display panel. The display panel includes a first display region, a base substrate, a pixel circuit layer, a planarization layer and a pixel defining layer.

The first display region includes pixel regions and light-transmissive regions.

The pixel circuit layer is disposed on one side of the base substrate.

The planarization layer is disposed on one side of the pixel circuit layer facing away from the base substrate and at least in the pixel regions.

The pixel defining layer is disposed on one side of the planarization layer facing away from the base substrate and in the pixel regions.

The pixel circuit layer and the planarization layer form a barrier wall, and the barrier wall is at least partially located between the pixel defining layer and a light-transmissive region.

In a third aspect, the embodiments of the present disclosure provide a display panel. The display panel includes a first display region, a base substrate, a first planarization layer, a second planarization layer, a third planarization layer and a pixel defining layer.

The first display region includes pixel regions and light-transmissive regions.

The first planarization layer, the second planarization layer and the third planarization layer are all disposed on one side of the base substrate, and in a direction facing away from the base substrate, the first planarization layer, the second planarization layer and the third planarization layer are sequentially laminated.

The pixel defining layer is disposed on one side of the third planarization layer facing away from the base substrate and in the pixel regions.

In a direction from the pixel defining layer to an adjacent light-transmissive region, the third planarization layer protrudes from the pixel defining layer.

In a fourth aspect, the embodiments of the present disclosure further provide a display device. The display device includes an under-screen photosensitive element and the display panel provided in the embodiments of the present disclosure. In a direction perpendicular to a plane where the display panel is located, the under-screen photosensitive element overlaps the light-transmissive region.

### BRIEF DESCRIPTION OF DRAWINGS

The drawings here are incorporated in the specification and form part of the specification to illustrate embodiments in accordance with the present disclosure and are intended to explain the principles of the present disclosure together with the description of the drawings.

To illustrate technical solutions in the embodiments of the present disclosure or in the related art more clearly, drawings used in description of the embodiments or the related art will be briefly described below. Apparently, those of ordinary skill in the art may obtain other drawings based on the drawings described below on the premise that no creative work is done.

FIG. 1 is a partial plan view of a first display region of a display panel according to an embodiment of the present disclosure;

FIG. 2 is a section view taken along A-B of FIG. 1;

FIG. 3 is a structural diagram of a protrusion portion according to an embodiment of the present disclosure;

FIG. 4 is a structural diagram of another protrusion portion according to an embodiment of the present disclosure;

FIG. 5 is a structural diagram of another protrusion portion according to an embodiment of the present disclosure;

FIG. 6 is a structural diagram of another protrusion portion according to an embodiment of the present disclosure;

FIG. 7 is a structural diagram of another protrusion portion according to an embodiment of the present disclosure;

FIG. 8 is another section view taken along A-B of FIG. 1;

FIG. 9 is another section view taken along A-B of FIG. 1;

FIG. 10 is another section view taken along A-B of FIG. 1;

FIG. 11 is another section view taken along A-B of FIG. 1;

FIG. 12 is another section view taken along A-B of FIG. 1;

FIG. 13 is another section view taken along A-B of FIG. 1;

FIG. 14 is a diagram showing the distribution of a display region according to an embodiment of the present disclosure;

FIG. 15 is another section view taken along A-B of FIG. 1;

FIG. 16 is another section view taken along A-B of FIG. 1;

FIG. 17 is another section view taken along A-B of FIG. 1; and

FIG. 18 is a structural diagram of a display device according to an embodiment of the present disclosure.

### DETAILED DESCRIPTION

To illustrate the purpose, features and advantages of the present disclosure more clearly, the technical solutions of the present disclosure will be further described. It is to be noted that if not in collision, the embodiments and features therein in the present disclosure may be combined with each other.

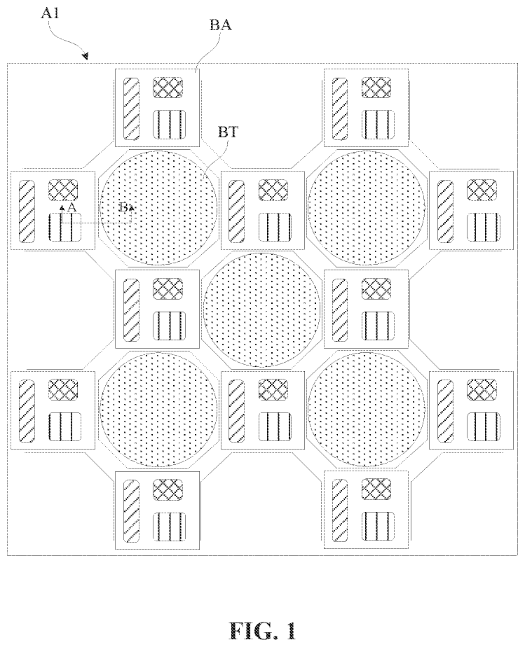

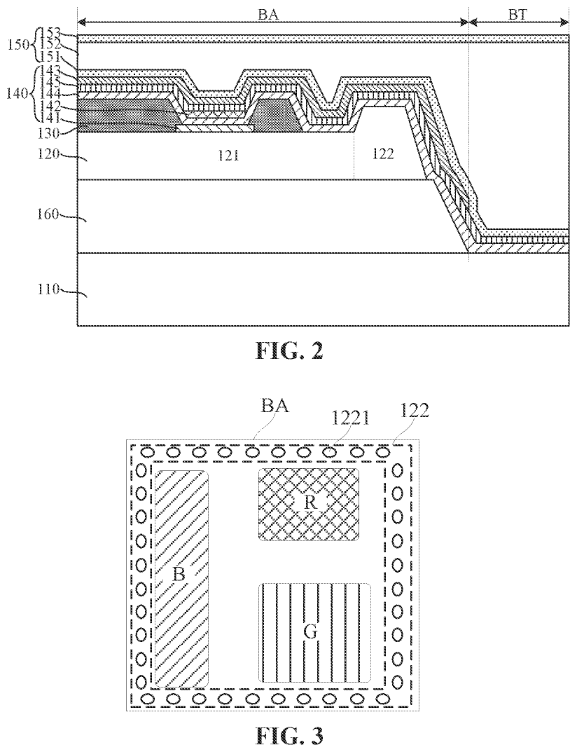

FIG. 1 is a partial plan view of a first display region of a display panel according to an embodiment of the present disclosure, and FIG. 2 is a section view taken along A-B of FIG. 1. As shown in FIG. 1 and FIG. 2, the display panel provided in the embodiment of the present disclosure includes a first display region A1, a base substrate 110, a planarization layer 120 and a pixel defining layer 130. The first display region A1 includes pixel regions BA and light-transmissive regions BT. The planarization layer 120 is disposed on one side of the base substrate 110 and at least in the pixel regions BA. The pixel defining layer 130 is disposed on one side of the planarization layer 120 facing away from the base substrate 110 and in the pixel regions BA. The planarization layer 120 includes flat portion 121 and protrusion portion 122, in a direction facing away from the base substrate 110, the protrusion portion 122 protrudes from the flat portion 121, and a protrusion portion 122 is at least partially located between the pixel defining layer 130 and a light-transmissive region BT.

The display panel provided in the embodiment of the present disclosure is applicable to a display device having an under-screen photosensitive element (such as an under-screen camera or an under-screen fingerprint recognition component). The first display region A1 is the under-screen photosensitive element region, which may be circular, elliptical, or polygonal in shape. The pixel regions BA are used for displaying the image and together with the second display region (see below) for displaying the complete image. The light-transmissive regions BT are used for transmitting light to improve the transmittance of the first display region A1, therefore ensuring the function of the under-screen photosensitive element (such as the camera function or the fingerprint recognition function). A pixel region BA includes multiple subpixels, such as red subpixels R, green subpixels G and blue subpixels B. Each subpixel can emit light of the corresponding color. Openings are provided in regions of various subpixels in the pixel defining layer 130 for defining light emission regions of the various subpixels. In the embodiment of the present disclosure, the pixel defining layer 130 may include a light-blocking material and may be set to black, and the light-blocking material may include at least one of resin, carbon black, carbon nanotubes or black dye. In this manner, the reflection of external light from the metal structure arranged below the pixel predefining layer 130 can be reduced.

Generally, the pixel defining layer 130 is prepared using an organic material, thus having a certain degree of fluidity. When a light-transmissive region BT is disposed on at least one side of a pixel region BA, the pixel defining layer 130 adjacent to the light-transmissive region BT can easily flow to the light-transmissive region BT if the pixel defining layer 130 is not blocked. Due to the light-blocking material included in the pixel defining layer 130, some of the light passing through the light-transmissive region BT is shielded. As a result, the transmittance of the light-transmissive region BT is reduced. On the basis of the technical solutions provided in the embodiment of the present disclosure, when the planarization layer including the flat portion 121 and the protrusion portion 122 is prepared, the pixel defining layer 130 is at least partially formed on the flat portion 121; in the direction facing away from the base substrate 110, the protrusion portion 122 protrudes from the flat portion 121, and a protrusion portion 122 is at least partially located between the pixel defining layer 130 and a light-transmissive region BT. In this manner, the protrusion portion 122 blocks at least part of the flow path of the pixel defining layer 130 to the light-transmissive region BT. During the process of the pixel defining layer 130 flowing to the light-transmissive region BT, the pixel defining layer 130 is blocked by the protrusion portion 122 and stops flowing to the light-transmissive region BT, so that the pixel defining layer 130 flowing to the light-transmissive region BT is reduced, and even the flow of the pixel defining layer 130 to the light-transmissive region BT can be completely avoided.

In some implementations, a subpixel includes a light-emitting device 140. The light-emitting device 140 includes a first electrode 141 (such as an anode), a light-emitting layer 142 and a second electrode 143 (such as a cathode). The light-emitting layer 142 is located between the first electrode 141 and the second electrode 143. The pixel defining layer 130 may be formed on the first electrode 141, an opening of the pixel defining layer 130 exposes the first electrode 141, the light-emitting layer 142 can be limited within the opening of the pixel defining layer 130, and the second electrode 143 covers the pixel region BA. In addition, the light-emitting device 140 may also include a first functional layer 144 and/or a second functional layer 145. Exemplarily, the first electrode 141 is the anode and the second electrode 143 is the cathode. In this case, the first functional layer may include a hole transport layer, or may include a hole transport layer and a hole injection layer; the second functional layer 145 may include an electron transport layer and/or an electron injection layer. The first functional layer 144 and/or the second functional layer 145 may cover the pixel region BA and the light-transmissive region BT.

In some implementations, the display panel further includes an encapsulation layer 150 disposed on one side of the second electrode 143 facing away from the base substrate 110, and the encapsulation layer 150 covers the pixel region BA and the light-transmissive region BT. Specifically, the encapsulation layer 150 may be a thin-film encapsulation layer and may include a first inorganic layer 151, a first organic layer 152 and a second inorganic layer 153. The first organic layer 152 is located between the first inorganic layer 151 and the second inorganic layer 153.

Moreover, in some embodiments, the display panel further includes a pixel circuit layer 160 located between the base substrate 110 and the planarization layer 120, and the pixel circuit layer 160 is located in the pixel regions BA. The pixel circuit layer 160 includes pixel circuits for driving light-emitting devices to emit light, including but not limited to 7T1C pixel circuits, 7T2C pixel circuits or 8T1C pixel circuits. The 7T1C pixel circuit includes 7 thin-film transistors and 1 capacitor, the 7T2C pixel circuit includes 7 thin-film transistors and 2 capacitors, and the 8T1C pixel circuit includes 8 thin-film transistors and 1 capacitor. The pixel circuit layer includes multiple insulating layers (such as a gate insulating layer and an interlayer insulating layer) covering the pixel regions BA, so that electrical insulation can be achieved between some film layers (such as a gate layer, an active layer and a source-drain layer) in the pixel circuits.

According to the display panel provided in the preceding implementations, the protrusion portion is formed on the planarization layer under the pixel defining layer, in the direction facing away from the base substrate, the protrusion portion protrudes from the flat portion, and a protrusion portion is at least partially located between the pixel defining layer and a light-transmissive region. The protrusion portion can effectively prevent the pixel defining layer from flowing to the light-transmissive region, so that the transmittance of the light-transmissive region is improved, and the impact on the function of the under-screen photosensitive element is avoided.

In some implementations, the protrusion portion includes multiple point-shaped protrusions and/or segment-shaped protrusions.

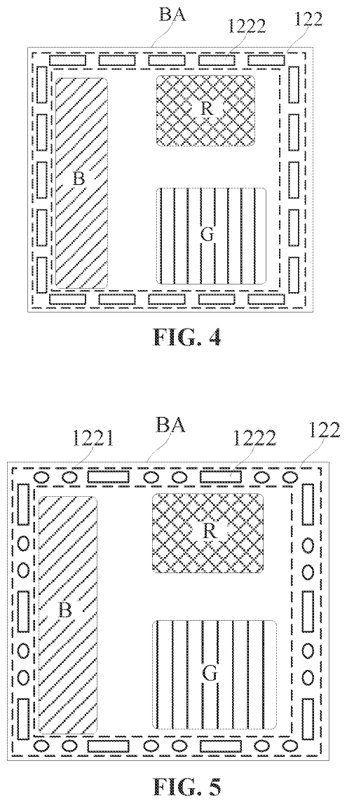

Exemplarily, as shown in FIG. 3 (the figure schematically shows that the pixel region BA includes a red subpixel R, a green subpixel G and a blue subpixel B, and colors of subpixels and pixel arrangement are not limited in the present disclosure), the protrusion portion 122 includes multiple point-shaped protrusions 1221, and the pixel defining layer will be blocked by the point-shaped protrusions 1221 and stop flowing when pixel defining layer flowing to the point-shaped protrusions 1221, so that the shielding of the pixel defining layer to the light-transmissive region is reduced, and the transmittance of the light-transmissive region is improved. In the embodiment, the spacing between point-shaped protrusions 1221 may be reduced so that the pixel defining layer flowing to the light-transmissive region can be reduced. In addition, as shown in FIG. 4, the protrusion portion 122 also includes multiple segment-shaped protrusions 1222, which extend along edges of the pixel defining layer and may be in the shape of long bars or arcs. Multiple segment-shaped protrusions 1222 can block most of the pixel defining layer flowing to the light-transmissive region, thereby reducing the shielding of the pixel defining layer to the light-transmissive and improving the transmittance of the light-transmissive region. In addition, as shown in FIG. 5 (the figure only schematically shows an arrangement manner of point-shaped protrusions 1221 and segment-shaped protrusions 1222, and the arrangement manner is not limited in the present disclosure), the protrusion portion 122 may also include both point-shaped protrusions 1221 and segment-shaped protrusions 1222. The point-shaped protrusions 1221 and the segment-shaped protrusions 1222 jointly block the pixel defining layer, so that the transmittance of the light-transmissive region is improved.

It is to be understood that the protrusion portion 122 shown in FIG. 3, FIG. 4 and FIG. 5 all completely surround the pixel defining layer. However, the configuration of the protrusion portion 122 is not limited in the present disclosure. The protrusion portion 122 may be disposed on the side of the pixel defining layer closest to the light-transmissive region, or may be disposed on both the side of the pixel defining layer close to the light-transmissive region and another side of the pixel defining layer (such as an adjacent side of the side closest to the light-transmissive region), but not completely around the pixel defining layer.

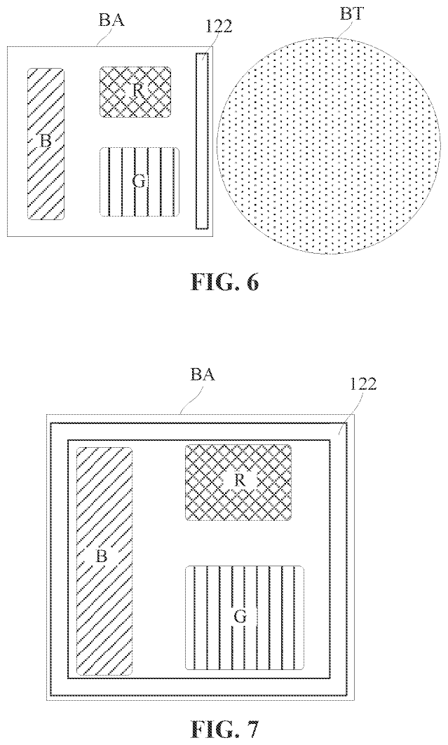

In addition, the protrusion portion may also be a continuous and integrated portion, so that the pixel defining layer flowing to the light-transmissive region is further reduced, and the transmittance of the light-transmissive region is further improved. Accordingly, in some implementations, the protrusion portion is disposed around the side of the pixel defining layer closest to the light-transmissive region. Exemplarily, as shown in FIG. 6, for the pixel region BA located on an edge (reference may be made to FIG. 1), one side (reference is made to FIG. 6) or three sides of the pixel defining layer are close to the light-transmissive region BT. At this time, a continuous protrusion portion 122 is simply disposed on the side of the pixel defining layer closest to the light-transmissive region BT, so that the pixel defining layer can be effectively prevented from flowing to the light-transmissive region BT, and thus the transmittance of the light-transmissive region can be improved.

It is to be noted that the side of the pixel defining layer close to the light-transmissive region does not refer to that only one side of the pixel defining layer is close to the light-transmissive region, but should include all sides of the pixel defining layer close to the light-transmissive region.

Accordingly, in some other implementations, the protrusion portion completely surrounds the pixel defining layer. Exemplarily, as shown in FIG. 7, the entire continuous protrusion portion 122 is disposed completely around the pixel defining layer, so that the pixel defining layer flowing out of the pixel region BA can be avoided, the pixel defining layer flowing to the light-transmissive region is avoided, and thus the transmittance of the light-transmissive region is improved. Moreover, protrusion portions 122 in all pixel regions BA are exactly the same, so that specific design for protrusion portions 122 in different pixel regions BA (such as an edge pixel region and a middle pixel region) can be avoided, and the patterning of the planarization layer becomes simple.

In some implementations, a flat portion is connected to the protrusion portion. Referring to FIG. 2, the flat portion 121 is connected to the protrusion portion 122. At this time, the protrusion portion 122 plays a role in blocking the pixel defining layer, so that the pixel defining layer is prevented from flowing to the light-transmissive region, and the transmittance of the light-transmissive region is improved. Optionally, the flat portion 121 and the protrusion portion 122 are integrally formed.

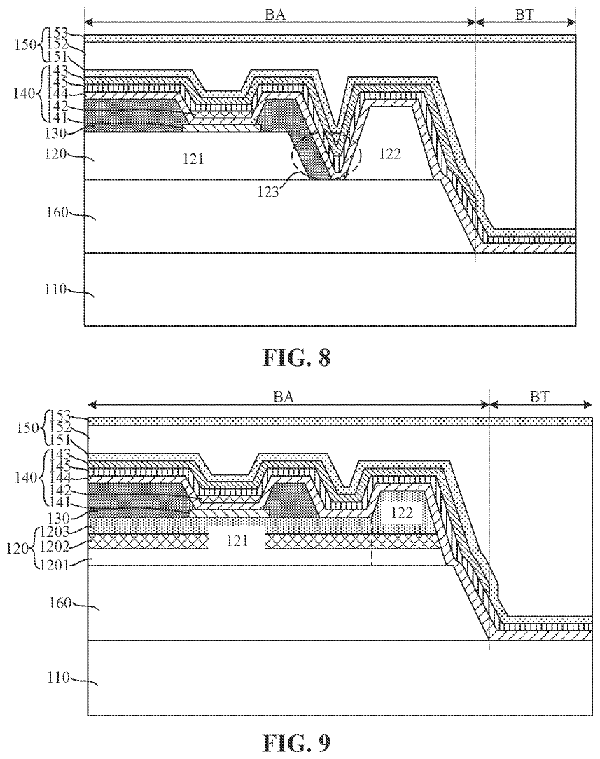

In some implementations, a groove is formed between a flat portion and the protrusion portion. As shown in FIG. 8, the planarization layer 120 includes the flat portion 121 and the protrusion portion 122, and the groove 123 is formed between the flat portion 121 and the protrusion portion 122. The pixel defining layer 130 is partially located in the groove 123. During the process of the pixel defining layer 130 flowing to the light-transmissive region BT, the pixel defining layer 130 will partially fill the groove 123. At this time, the groove 123 forms an accommodation space for the pixel defining layer 130, which can accommodate part of the pixel defining layer 130 or the entire pixel defining layer 130 flowing to the light-transmissive region. Moreover, the protrusion portion 122 is still disposed in the flow path of the pixel defining layer 130 behind the groove 123. In some cases, the pixel defining layer 130 that overflows from the groove 123 will be further blocked by the protrusion portion 122 and stop flowing to the light-transmissive region BT. At this time, the protrusion portion 122 plays a role in secondarily blocking the pixel defining layer 130. In this manner, in the implementation, the corporation of the groove and the protrusion portion can further prevent the pixel defining layer 130 from flowing to the light-transmissive region BT, ensuring that the transmittance of the light-transmissive region BT is not affected by the pixel defining layer 130.

It is to be noted that FIG. 8 only schematically shows an implementable structure of the display panel. In some implementations, the groove 123 may not be adjacent to the protrusion portion 122, and the groove 123 may not penetrate through the planarization layer 120. The implementable structure is not limited in the present disclosure and is specifically determined according to actual situations.

Accordingly, in some implementations, the groove is disposed at least around the side of the pixel defining layer closest to the adjacent light-transmissive region. For the surrounding of the groove to the pixel defining layer in the implementation, reference may be made to the surrounding of the protrusion portion to the groove in the preceding implementation, which is not repeated here.

In some implementations, the groove completely surrounds the pixel defining layer. In this manner, the patterning of the planarization layer is relatively simple while the pixel defining layer is prevented from flowing to the light-transmissive region.

In some implementations, the planarization layer includes a first planarization layer, a second planarization layer and a third planarization layer which are sequentially laminated in the direction facing away from the base substrate. The third planarization layer includes the protrusion portion, or the second planarization layer includes the protrusion portion.

Exemplarily, as shown in FIG. 9, the planarization layer 120 includes a first planarization layer 1201, a second planarization layer 1202 and a third planarization layer 1203. The second planarization layer 1202 is located between the first planarization layer 1201 and the third planarization layer 1203, the third planarization layer 1203 is disposed on one side of the second planarization layer 1202 facing away from the base substrate 110, and the pixel defining layer 130 is disposed on one side of the third planarization layer 1203 facing away from the base substrate 110. The third planarization layer 1203 includes the protrusion portion 122. In the embodiment, the third planarization layer 1203 extends towards the direction of the light-transmissive region BT, and the protrusion portion 122 is formed at the end of the extension of the third planarization layer 1203. The protrusion portion 122 blocks the flow of the pixel defining layer 130 to the light-transmissive region BT, so that the transmittance of the light-transmissive region BT is improved.

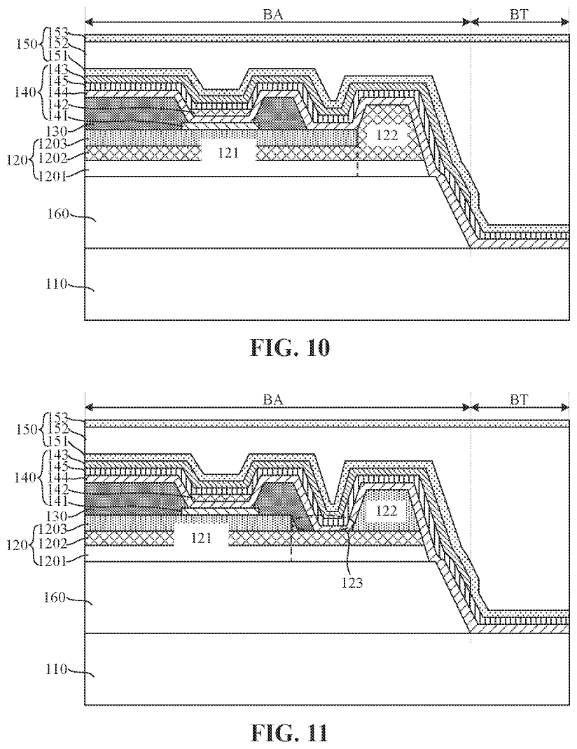

Optionally, as shown in FIG. 10, the display panel in FIG. 10 differs from the display panel shown in FIG. 9 in that the second planarization 1202 in the display panel includes the protrusion portion 122. Similarly, in the example, the second planarization layer 1202 extends towards the direction of the light-transmissive region BT, and the protrusion portion 122 is formed at the end of the extension of the second planarization layer 1202. The protrusion portion 122 blocks the flow of the pixel defining layer 130 to the light-transmissive region BT, so that the transmittance of the light-transmissive region BT is improved.

On the basis of the preceding embodiments where the groove is provided, in some implementations, the planarization layer includes a first planarization layer, a second planarization layer and a third planarization layer which are sequentially laminated in the direction facing away from the base substrate, and the groove is formed at least in the third planarization layer.

Exemplarily, as shown in FIG. 11, the planarization layer 120 includes a first planarization layer 1201, a second planarization layer 1202 and a third planarization layer 1203. The second planarization layer 1202 is located between the first planarization layer 1201 and the third planarization layer 1203, the third planarization layer 1203 is disposed on one side of the second planarization layer 1202 facing away from the base substrate 110, and the pixel defining layer 130 is disposed on one side of the third planarization layer 1203 facing away from the base substrate 110. The third planarization layer 1203 includes the protrusion portion 122, and the groove 123 is formed in the third planarization layer 1203. In this manner, on the one hand, the groove 123 is formed in the third planarization layer 1203, and the groove is used as an accommodation space for the pixel defining layer 130, which can accommodate part of the pixel defining layer 130 or the entire pixel defining layer 130 flowing to the light-transmissive region BT. On the other hand, the protrusion portion 122 is formed at the end of the third planarization layer 1203, and the protrusion portion 122 further blocks the pixel defining layer 130 overflowing from the groove 123, which ensures that the transmittance of the light-transmissive region BT is not affected by the pixel defining layer 130.

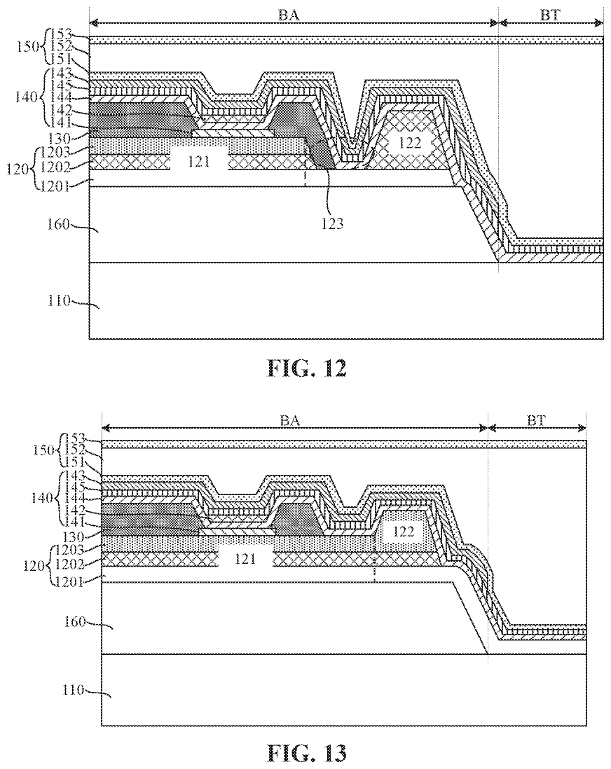

Optionally, as shown in FIG. 12, the planarization layer 120 includes a first planarization layer 1201, a second planarization layer 1202 and a third planarization layer 1203. The second planarization layer 1202 is located between the first planarization layer 1201 and the third planarization layer 1203, the third planarization layer 1203 is disposed on one side of the second planarization layer 1202 facing away from the base substrate 110, and the pixel defining layer 130 is disposed on one side of the third planarization layer 1203 facing away from the base substrate 110. The second planarization layer 1202 includes the protrusion portion 122, and the groove 123 is formed in the third planarization layer 1203 and the second planarization layer 1202. In this manner, on the one hand, the groove 123 is formed in the third planarization layer 1203 and the second planarization layer 1202, the groove is used as an accommodation space for the pixel defining layer 130, which can accommodate part of the pixel defining layer 130 or the entire pixel defining layer 130 flowing to the light-transmissive region BT. On the other hand, the protrusion portion 122 is formed at the end of the second planarization layer 1202, and the protrusion portion 122 further blocks the pixel defining layer 130 overflowing from the groove 123, which ensures that the transmittance of the light-transmissive region BT is not affected by the pixel defining layer 130.

In some implementations, the groove penetrates through the third planarization layer and the second planarization layer. In the structures of the display panel shown in FIG. 11 and FIG. 12, the groove 123 can penetrate through both the third planarization layer 1203 and the second planarization layer 1202. In this manner, the groove 123 can form a bigger accommodation space, further preventing the pixel defining layer 130 from flowing to the light-transmissive region BT.

In some implementations, the planarization layer includes a first planarization layer, a second planarization layer and a third planarization layer which are sequentially laminated in the direction facing away from the base substrate; and the second planarization layer and the third planarization layer are located in the pixel region, and the first planarization layer is located in the pixel region and the light-transmissive region.

As shown in FIG. 13, the planarization layer 120 includes a first planarization layer 1201, a second planarization layer 1202 and a third planarization layer 1203. The second planarization layer 1202 is located between the first planarization layer 1201 and the third planarization layer 1203, the third planarization layer 1203 is disposed on one side of the second planarization layer 1202 facing away from the base substrate 110, and the pixel defining layer 130 is disposed on one side of the third planarization layer 1203 facing away from the base substrate 110. The second planarization layer 1202 and the third planarization layer 1203 are located in the pixel regions BA, and the first planarization layer 1204 is located in the pixel regions BA and the light-transmissive regions BT. In this manner, the first planarization layer 1201 is disposed in the pixel regions BA and the light-transmissive regions BT, and the second planarization layer 1202 and the third planarization layer 1203 are only disposed in the pixel regions BA, so that film layers on the first planarization layer 1201 located in the light-transmissive regions BT are relatively flat while the number of film layers in the light-transmissive regions BT is minimized, and thus the impact of light refraction is reduced.

In some implementations, part of the first planarization layer located in the light-transmissive regions covers a surface of the base substrate. In this manner, all film layers between the first planarization layer in the light-transmissive regions and the base substrate are removed by etching, so that the number of film layers in the light-transmissive regions is further reduced, and then the impact of light refraction is further reduced.

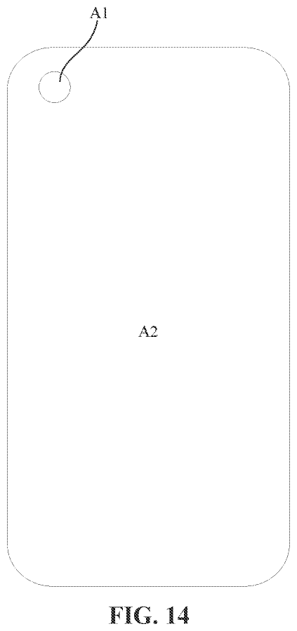

In some implementations, the display panel further includes a second display region, the second display region at least partially surrounds the first display region, and the transmittance of the second display region is less than the transmittance of the first display region. Exemplarily, as shown in FIG. 14, the display panel includes the first display region A1 and the second display region A2 (corresponding to the active display region in the notch screen). The second display region A2 completely surrounds the first display region A1, and the transmittance of the second display region A2 is less than the transmittance of the first display region A1. In this manner, it is not necessary to set light-transmissive regions in the second display region A2, and the second display region A is set with a relatively higher pixel density, so that the resolution of the image display is improved.

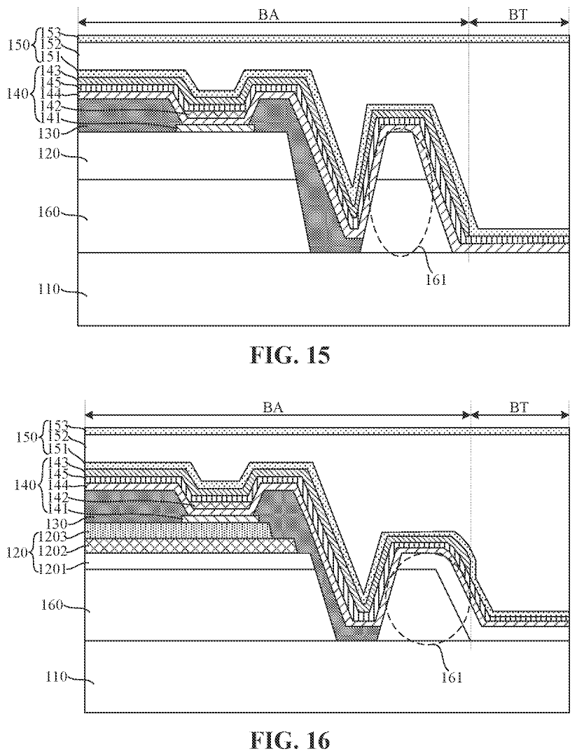

An embodiment of the present disclosure further provides a display panel. FIG. 15 is another section view taken along A-B of FIG. 1. As shown in FIG. 1 and FIG. 15, the display panel includes a first display region A1, a base substrate 110, a pixel circuit layer 160, a planarization layer 120 and a pixel defining layer 130. The first display region A1 includes pixel regions BA and light-transmissive regions BT. The pixel circuit layer 160 is disposed on one side of the base substrate 110. The planarization layer 120 is disposed on one side of the pixel circuit layer 160 facing away from the base substrate 110 and at least in the pixel regions BA. The pixel defining layer 130 is disposed on one side of the planarization layer 120 facing away from the base substrate 110 and in the pixel regions BA. The pixel circuit layer 160 and the planarization layer 120 form a barrier wall 161, and the barrier wall 161 is at least partially located between the pixel defining layer 130 and a light-transmissive region BT.

Generally, the pixel defining layer 130 is prepared using an organic material, thus having a certain degree of fluidity. When a light-transmissive region BT is disposed on at least one side of a pixel region BA, the pixel defining layer 130 adjacent to the light-transmissive region BT can easily flow to the light-transmissive region BT if the pixel defining layer 130 is not blocked. Due to the light-blocking material included in the pixel defining layer 130, some of the light passing through the light-transmissive region BT is shielded. As a result, the transmittance of the light-transmissive region BT is reduced. On the basis of the technical solutions provided in the embodiment of the present disclosure, the pixel circuit layer 160 and the planarization 120 which are close to the light-transmissive region BT form the barrier wall 161, and the barrier wall is at least partially located between the pixel defining layer 130 and the light-transmissive region BT. Accordingly, a groove must exist between the barrier wall 161 and the remaining pixel circuit layer 160 and the remaining planarization layer 120 of the pixel region BA. Therefore, the pixel defining layer 130 will flow to the groove and then be blocked by the barrier wall 161, so that the pixel defining layer 130 cannot continue to flow to the light-transmissive region BT, and thus the transmittance of the light-transmissive region BT is improved.

In some embodiments, the pixel circuit layer 160 includes pixel circuits for driving light-emitting devices to emit light. The pixel circuit layer 160 includes multiple insulating layers covering the pixel regions BA, and the barrier wall is formed by the planarization layer 120 and the multiple insulating layers in the pixel circuit layer 160.

According to the display panel provided in the preceding implementation, the pixel circuit layer and the planarization layer form the barrier wall, and the barrier wall is at least partially located between the pixel defining layer and the light-transmissive region. In this manner, the barrier wall can effectively block the pixel defining layer flowing to the light-transmissive region, so that the transmittance of the light-transmissive region is improved, and the impact on the function of the under-screen photosensitive element is avoided.

In some implementations, the barrier wall is disposed around one side of the pixel defining layer facing towards the light-transmissive region. For the pixel region BA located on an edge (reference may be made to FIG. 1), one side or three sides of the pixel defining layer are close to the light-transmissive region BT. At this time, a continuous barrier wall 161 is simply disposed on the side of the pixel defining layer close to the light-transmissive region BT, so that the pixel defining layer can be effectively prevented from flowing to the light-transmissive region BT, and thus the transmittance of the light-transmissive region can be improved.

In some implementations, the barrier wall completely surrounds the pixel defining layer. In this manner, the pixel defining layer can be prevented from flowing out of the pixel region BA, the pixel defining layer flowing to the light-transmissive region can be avoided, and thus the transmittance of the light-transmissive region is improved. Moreover, banks 161 in all pixel regions BA are exactly the same, so that specific design for banks 161 in different pixel regions BA (such as an edge pixel region and a middle pixel region) can be avoided, and the patterning of the planarization layer and the pixel circuit layer becomes simple.

On the basis of the preceding implementations, in a specific implementation, as shown in FIG. 16, the planarization layer 120 includes a first planarization layer 1201, a second planarization layer 1202 and a third planarization layer 1203. The second planarization layer 1202 is located between the first planarization layer 1201 and the third planarization layer 1203, the third planarization layer 1203 is disposed on one side of the second planarization layer 1202 facing away from the base substrate 110, and the pixel defining layer 130 is disposed on one side of the third planarization layer 1203 facing away from the base substrate 110. The second planarization layer 1202 and the third planarization layer 1203 are located in the pixel regions BA, the first planarization layer 1204 is located in the pixel regions BA and the light-transmissive regions BT, and the first planarization layer 1207 and the pixel circuit layer 160 which are close to the light-transmissive regions BT form a barrier wall 161. In this manner, the first planarization layer 1201 and the pixel circuit layer 160 form the barrier wall 161, so that the pixel defining layer is prevented from flowing to the light-transmissive region BT, and thus the transmittance of the light-transmissive region is improved.

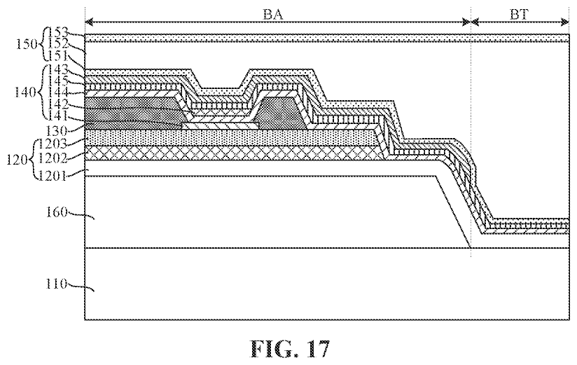

An embodiment of the present disclosure further provides a display panel. FIG. 17 is another section view taken along A-B of FIG. 1 As shown in FIG. 1 and FIG. 17, the display panel includes a first display region A1, a base substrate 110, a first planarization layer 1201, a second planarization layer 1202, a third planarization layer 1203 and a pixel defining layer 130. The first display region A1 includes pixel regions BA and light-transmissive regions BT. The first planarization layer 1201, the second planarization layer 1202 and the third planarization layer 1203 are all disposed on one side of the base substrate 110, and in a direction facing away from the base substrate 110, the first planarization layer 1201, the second planarization layer 1202 and the third planarization layer 1203 are sequentially laminated. The pixel defining layer 130 is disposed on one side of the third planarization layer 1203 facing away from the base substrate 110 and in the pixel regions BA. In a direction from the pixel defining layer 130 to an adjacent light-transmissive region BT, the third planarization layer 1203 protrudes from the pixel defining layer 130.

In the embodiment of the present disclosure, the third planarization layer 1203 extends along a direction towards the light-transmissive region BT, so that in the direction from the pixel defining layer 130 to the adjacent light-transmissive region BT, the third planarization layer 1203 protrudes from the pixel defining layer 130; therefore, the pixel defining layer 130 is located on the third planarization layer 1203, and the extension part of the third planarization layer 1203 forms a flow platform for the pixel defining layer 130. In this manner, flow paths of the pixel defining layer 130 in both the horizontal direction and the vertical direction are increased, thus the pixel defining layer 130 flowing to the light-transmissive region BT is reduced, and the transmittance of the light-transmissive region BT is improved.

In some implementations, a side surface of the third planarization layer 1203 closest to the light-transmissive region BT may be flush with a side surface of the second planarization layer 1202 closest to the light-transmissive region BT, or the third planarization layer 1203 covers a side surface of the second planarization layer 1202 closest to the light-transmissive region BT, or in the direction from the pixel defining layer to the light-transmissive region BT, the second planarization 1202 protrudes from the third planarization layer 1203. The preceding is not limited in the present disclosure, as long as the third planarization layer 1203 protrudes from the pixel defining layer 130 in the direction from the pixel defining layer 130 to the adjacent light-transmissive region BT.

According to the display panel provided in the preceding implementation, the third planarization layer extends towards the direction of the light-transmissive region, and the third planarization layer is used for extending the flow path of the pixel defining layer, so that the pixel defining layer flowing to the light-transmissive region is reduced, and thus the transmittance of the light-transmissive region is improved.

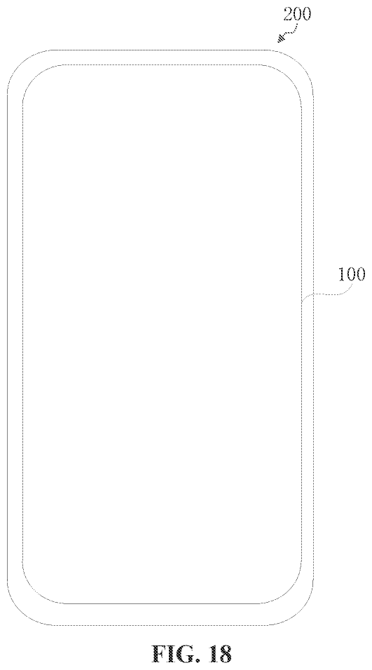

In addition, an embodiment of the present disclosure further provides a display device. As shown in FIG. 18, the display device 200 includes an under-screen photosensitive element and the display panel 100 provided in any embodiment of the present disclosure. In a direction perpendicular to the plane where the display panel 100 is located, the under-screen photosensitive element overlaps the light-transmissive region. The display device 200 may be another display device with the display function such as a mobile phone, a computer, a television and a vehicle-mounted display device, which is not limited in the embodiment of the present disclosure. The display device 200 provided in the embodiment of the present disclosure has the beneficial effects of the display panel provided in the embodiments of the present disclosure. For details, reference may be made to the specific description of the display panel in the preceding implementations, and the details are not repeated here in the embodiment of the present disclosure.

It is to be noted that herein, relationship terms such as “first” and “second” are used merely for distinguishing one entity or operation from another, and do not necessarily require or imply any such actual relationship or order between these entities or operations. Furthermore, the term “comprising”, “including” or any other variant thereof is intended to encompass a non-exclusive inclusion so that a process, method, article or device that includes a series of elements not only includes the expressly listed elements but also include other elements that are not expressly listed or are inherent to such a process, method, article or device. In the absence of more restrictions, the elements defined by the statement “including a . . . ” do not exclude the presence of additional identical elements in the process, method, article or device that includes the elements.

The preceding are merely specific embodiments of the present disclosure to enable those skilled in the art to understand or implement the present disclosure. Various modifications to these embodiments will be apparent to those skilled in the art, and the general principles defined herein may be implemented in other embodiments without departing from the spirit or scope of the disclosure. Therefore, the present disclosure is not intended to be limited to the embodiments shown herein but is to accord with the widest scope consistent with the principles and novel features disclosed herein.

What is claimed is:

1. A display panel, comprising:
a first display region, wherein the first display region comprises pixel regions and light-transmissive regions;
a base substrate;
a planarization layer, wherein the planarization layer is disposed on one side of the base substrate and at least in the pixel regions; and
a pixel defining layer, wherein the pixel defining layer is disposed on one side of the planarization layer facing away from the base substrate and in the pixel regions;
wherein the planarization layer comprises a flat portion and a protrusion portion, in a direction facing away from the base substrate, protrusion portion protrudes from the flat portion, and the protrusion portion is at least partially located between the pixel defining layer and a light-transmissive region of the light-transmissive regions.

2. The display panel according to claim 1, wherein the protrusion portion comprises a plurality of point-shaped protrusions and/or segment-shaped protrusions.

3. The display panel according to claim 1, wherein the protrusion portion is disposed around one side of the pixel defining layer facing towards the light-transmissive region.

4. The display panel according to claim 1, wherein the pixel defining layer is completely surrounded by the protrusion portion.

5. The display panel according to claim 1, wherein the flat portion is connected to the protrusion portion.

6. The display panel according to claim 1, wherein a groove is formed between the flat portion and the protrusion portion.

7. The display panel according to claim 6, wherein the groove is disposed at least around one side of the pixel defining layer facing towards an adjacent light-transmissive region.

8. The display panel according to claim 7, wherein the pixel defining layer is completely surrounded by the groove.

9. The display panel according to claim 1, wherein the planarization layer comprises a first planarization layer, a second planarization layer and a third planarization layer which are sequentially laminated in the direction facing away from the base substrate; and
the third planarization layer comprises the protrusion portion, or the second planarization layer comprises the protrusion portion.

10. The display panel according to claim 6, wherein the planarization layer comprises a first planarization layer, a second planarization layer and a third planarization layer which are sequentially laminated in the direction facing away from the base substrate; and
the groove is formed at least in the third planarization layer.

11. The display panel according to claim 10, wherein the groove penetrates through the third planarization layer and the second planarization layer.

12. The display panel according to claim 6, wherein the pixel defining layer is partially located in the groove.

13. The display panel according to claim 1, wherein the planarization layer comprises a first planarization layer, a second planarization layer and a third planarization layer which are sequentially laminated in the direction facing away from the base substrate; and
the second planarization layer and the third planarization layer are located in the pixel regions, and the first planarization layer is located in the pixel regions and the light-transmissive regions.

14. The display panel according to claim 13, wherein a part of the first planarization layer located in the light-transmissive regions covers a surface of the base substrate.

15. The display panel according to claim 1, wherein the display panel further comprises a second display region, the second display region at least partially surrounds the first display region, and transmittance of the second display region is less than transmittance of the first display region.

16. A display panel, comprising:
a first display region, wherein the first display region comprises pixel regions and light-transmissive regions;
a base substrate;
a pixel circuit layer, wherein the pixel circuit layer is disposed on one side of the base substrate;
a planarization layer, wherein the planarization layer is disposed on one side of the pixel circuit layer facing away from the base substrate and at least in the pixel regions; and
a pixel defining layer, wherein the pixel defining layer is disposed on one side of the planarization layer facing away from the base substrate and in the pixel regions;
wherein the pixel circuit layer and the planarization layer form a barrier wall, and the barrier wall is at least partially located between the pixel defining layer and a light-transmissive region of the light-transmissive regions.

17. The display panel according to claim 16, wherein the barrier wall is disposed around one side of the pixel defining layer facing towards the light-transmissive region.

18. The display panel according to claim 16, wherein the pixel defining layer is completely surrounded by the barrier wall.

19. A display panel, comprising:
a first display region, wherein the first display region comprises pixel regions and light-transmissive regions;
a base substrate;
a first planarization layer, a second planarization layer and a third planarization layer, wherein the first planarization layer, the second planarization layer and the third planarization layer are all disposed on one side of the base substrate, and in a direction facing away from the base substrate, the first planarization layer, the second planarization layer and the third planarization layer are sequentially laminated; and
a pixel defining layer, wherein the pixel defining layer is disposed on one side of the third planarization layer facing away from the base substrate and in the pixel regions;
wherein in a direction from the pixel defining layer to an adjacent light-transmissive region of the light-transmissive regions, the third planarization layer protrudes from the pixel defining layer.

20. A display device, comprising an under-screen photosensitive element and the display panel according to claim 1, wherein in a direction perpendicular to a plane where the display panel is located, the under-screen photosensitive element overlaps the light-transmissive region.
